(19) United States
(12) Patent Application Publication
(10) Pub. No.: US 2025/0219022 A1
(43) Pub. Date: Jul. 3, 2025

(54) EMBEDDED ACTIVE CHIP WITHIN INTERPOSER

(71) Applicant: International Business Machines Corporation, Armonk, NY (US)

(72) Inventors: Manasa MEDIKONDA, ALBANY, NY (US); Tao LI, Slingerlands, NY (US); Ruilong Xie, Niskayuna, NY (US); Cheng Chi, Jersey City, NJ (US); Joshua M. Rubin, Albany, NY (US)

(21) Appl. No.: 18/398,243

(22) Filed: Dec. 28, 2023

(51) Int. Cl. H01L 25/065; H01L 21/56; H01L 21/768; H01L 23/00; H01L 23/48; H01L 23/528; H01L 25/00; H10B 80/00

(52) U.S. Cl. CPC H01L 25/0652; H01L 21/56; H01L 21/76898; H01L 23/481; H01L 23/5286; H01L 25/50; H10B 80/00; H01L 24/16; H01L 2224/16145

(57) ABSTRACT

A semiconductor device comprises a wafer with an active interposer comprising one or more active components in an active component layer. The semiconductor device comprises a first chiplet that is mounted on the wafer and above the active interposer, a second chiplet that is mounted on the wafer and above the active interposer, and an interconnect layer having an interconnection that bridges between the first chiplet and the second chiplet. The interconnect layer is configured to transfer at least one of power and a signal from a bottom-side bump on a bottom side of the wafer to at least one of the first chiplet and the second chiplet, directly or indirectly, through a TSV of the active interposer.

### BACKGROUND

The manufacture of semiconductor chips and their respective mounting has advanced significantly in recent years. Numerous applications, such as accelerators/graphical processing units (GPUs) with high bandwidth memories (HBMs), split microprocessor chips, and other heterogeneous integration schemes require High Density Interconnect (HDI) solutions with high bandwidth and low latency with sufficient power distribution.

Interposers have been the traditional solution for high performance systems with HBMs. An interposer is an electrical interface routing between one socket or connection to another. The general purpose of an interposer is to spread a connection to a wider pitch or to reroute a connection to a different connection. Interposers are often used in ball grid array (BGA) packages, multi-chip modules and high bandwidth memory. A common example of an interposer is an integrated circuit die to BGA. This is done through various substrates, both rigid and flexible, most commonly FR4 for rigid, and polyimide for flexible. Interposer stacks are also an alternative to 3D integrated circuits (ICs). Combinations of small dies (also called “chiplets”) may be bonded on an interposer.

### SUMMARY

Disclosed herein is a semiconductor device comprising a wafer with an active interposer comprising one or more active components in an active component layer. The semiconductor device comprises a first chiplet that is mounted on the wafer and above the active interposer, a second chiplet that is mounted on the wafer and above the active interposer, and an interconnect layer having an interconnection that bridges between the first chiplet and the second chiplet. The interconnect layer is configured to transfer at least one of power and a signal from a bottom-side bump on a bottom side of the wafer to at least one of the first chiplet and the second chiplet, directly or indirectly, through a TSV of the active interposer.

Disclosed herein is also a method for manufacturing a semiconductor device. The method comprises forming vias in a wafer, forming an interposer trench in the wafer, and attaching an active interposer comprising one or more active components and interposer vias to the wafer and within the interposer trench. The method further comprises filling, with an interposer fill material, and planarizing the interposer trench. The method further comprises adding pattern contacts layer with pattern contacts on top of the active interposer and that contact the interposer vias. The method further comprises joining a first chiplet and a second chiplet to the semiconductor device above the active interposer that contact the pattern contacts. The method further comprises providing a mold fill layer that surrounds at least a portion of the first chiplet and the second chiplet and is above the pattern contacts layer and planarizing the mold fill layer, revealing a backside on a bottom surface of the active interposer, and providing a bottom layer below the bottom surface comprising backside contacts and bumps.

Disclosed herein is also a semiconductor device comprising a chip, an active interposer region of an active interposer comprising one or more active components in an active component layer, a passive interposer region that contains no active components, and an interconnect layer that is configured to transfer at least one of power and a signal from a bottom-side bump on a bottom side of the chip to a device located above the active interposer region, directly or indirectly, through a via of the active interposer.

### BRIEF DESCRIPTION OF THE DRAWINGS

The aspects defined above, and further aspects disclosed herein, are apparent from the examples of one or more embodiments to be described hereinafter and are explained with reference to the examples of the one or more embodiments, but to which the invention is not limited. Various embodiments are described, by way of example only, and with reference to the following drawings:

FIG. 1A is a cross-sectional side view a chip according to a first embodiment.

FIG. 1B is a cross-sectional side view a chip according to a second embodiment.

FIGS. 2A-2I are cross-sectional side views of the chip in FIG. 1A throughout various operations of its manufacturing process, as described in FIG. 6.

FIG. 2A is a cross-sectional side view of the chip in FIG. 1A after blind through silicon vias (TSVs) in a silicon wafer.

FIG. 2B is a cross-sectional side view of the chip in FIG. 1A after etching a trench.

FIG. 2C is a cross-sectional side view of the chip in FIG. 1A after attaching the active interposer.

FIG. 2D is a cross-sectional side view of the chip in FIG. 1A after filling the trench and planarizing the top surface.

FIG. 2E is a cross-sectional side view of the chip in FIG. 1A after adding pattern contacts.

FIG. 2F is a cross-sectional side view of the chip in FIG. 1A after joining a GPU and an HBM and providing an underfill.

FIG. 2G is a cross-sectional side view of the chip in FIG. 1A after adding a mold fill layer and planarizing this layer.

FIG. 2H is a cross-sectional side view of the chip in FIG. 1A after planarizing the bottom of the silicon wafer.

FIG. 2I is a cross-sectional side view of the chip in FIG. 1A after a TSV capture by adding a bottom layer at the bottom surface, and providing bottom layer backside contacts.

FIGS. 3A-3J are cross-sectional side views of the chip in FIG. 1B throughout its manufacturing process, as described in FIG. 7.

FIG. 3A is a cross-sectional side view of the chip in FIG. 1B after forming blind through vias, such as blind through silicon vias (TSVs) 304 in a silicon wafer.

FIG. 3B is a cross-sectional side view of the chip in FIG. 1B after etching a trench.

FIG. 3C is a cross-sectional side view of the chip in FIG. 1B after attaching the active interposer.

FIG. 3D is a cross-sectional side view of the chip in FIG. 1B after adding a fill material and planarizing the top surface.

FIG. 3E is a cross-sectional side view of the chip in FIG. 1B after planarizing the top surface.

FIG. 3F is a cross-sectional side view of the chip in FIG. 1B after adding pattern contacts down through an interposer layer.

FIG. 3G is a cross-sectional side view of the chip in FIG. 1B after joining a GPU and an HBM to a top surface of the interposer layer and providing an underfill.

FIG. 3H is a cross-sectional side view of the chip in FIG. 1B after adding a mold fill layer and planarizing this layer.

FIG. 3I is a cross-sectional side view of the chip in FIG. 1B after planarizing the bottom of the silicon wafer.

FIG. 3J is a cross-sectional side view of the chip in FIG. 1B after a TSV capture by adding a bottom layer at the bottom surface, and providing bottom layer backside contacts that connect to contacts in the blind TSVs or backside contacts that go through the bottom layer.

FIG. 4 is a block diagram (top view, not to scale) of an example use case showing a large QCM interposer having a small active region, according to some embodiments.

FIG. 5A is a cross-sectional side view of a chip illustrating a decoupling of the accelerator power distribution and LY scratchpad design, according to some embodiments.

FIG. 5B is a top view of the chip described in FIG. 5A.

FIG. 6 is a flowchart illustrating an example of a method for manufacturing the chip according to the first embodiment.

FIG. 7 is a flowchart illustrating an example of a method for manufacturing the chip according to the second embodiment.

### DETAILED DESCRIPTION

Various embodiments are described herein with reference to different subject-matter. In particular, some embodiments may be described with reference to methods, whereas other embodiments may be described with reference to apparatuses and systems. However, a person skilled in the art will gather from the above and the following description that, unless otherwise notified, in addition to any combination of features belonging to one type of subject-matter, also any combination between features relating to different subject-matter, in particular, between features of the methods, and features of the apparatuses and systems, are considered as to be disclosed within this document. The descriptions of the various embodiments of the present invention are presented for purposes of illustration, but are not intended to be exhaustive or limited to the embodiments disclosed. Many modifications and variations will be apparent to those of ordinary skill in the art without departing from the scope and spirit of the described embodiments. The terminology used herein has been chosen to best explain the principles of the embodiments, the practical application or technical improvement over technologies found in the marketplace, or to enable others of ordinary skill in the art to understand the embodiments disclosed herein.

Embedded Active Chip within Interposer

The following application-specific acronyms may be used below:

TABLE 1
Application-Specific Acronyms

| | |
|---|---|
| BEOL | back-end-of-line |
| BGA | ball grid array |
| C2C | chip-to-chip |
| C4 | controlled collapse chip connection |
| CoWoS | chip-on-wafer-on-substrate |
| DAF | die attached film |
| GPU | graphical processing unit |
| HBM | high bandwidth memory |
| HDI | High Density Interconnect |
| IC | integrated circuit |
| i-THOP ® | integrated thin-film high-density organic package |
| MIM | metal-insulator-metal |
| QCM | quad chip module |
| RDL | redistribution layer |
| TSV | through silicon via |

TABLE 2
Table of Reference Numbers

| | |
|---|---|
| 200 | semiconductor device (embodiment 1) |
| 202 | chip, wafer portion, silicon wafer |
| 204 | blind through vias, blind through silicon vias of wafer, wafer vias |
| 206 | trench, interposer trench |
| 208 | bottom surface of wafer |
| 210 | active interposer |
| 212 | TSV of active interposer, blind TSV, interposer via |
| 214 | active interposer contacts |
| 217 | active component layer |
| 219 | interconnection |
| 220 | interposer fill material |
| 222 | top surface of fill material |
| 230 | pattern contacts layer, interposer layer |
| 232 | top surface of interposer layer |
| 234 | patterned contacts of pattern contacts layer |
| 240 | underfill |
| 242 | chiplet bonding bumps |
| 245 | mold fill layer |
| 250 | GPU, second chiplet |
| 260 | HBM, first chiplet |
| 270 | bottom layer, via capture layer |
| 272 | bottom layer vias |
| 274 | bottom layer backside contacts |
| 276 | bumps |
| 300 | semiconductor device (embodiment 2) |
| 302 | chip, wafer portion, silicon wafer |
| 304 | blind through vias, blind through silicon vias of wafer |
| 306 | trench |
| 308 | bottom surface of wafer |
| 310 | active interposer |
| 311 | carrier wafer portion |
| 312 | TSV of active interposer, blind TSV, interposer via |
| 313 | far BEOL layer |
| 314 | active interposer contacts |
| 315 | MIM capacitor, inductor layer |
| 316 | lower BEOL layer |
| 317 | switching devices layer, active component layer |
| 318 | backside interconnection layer |
| 319 | interconnection |
| 320 | interposer fill material |
| 322 | top surface of fill material |
| 330 | pattern contacts layer |
| 332 | top surface of pattern contacts layer |
| 334 | patterned contacts of pattern contacts layer |
| 340 | underfill |
| 345 | mold fill layer |
| 350 | GPU, second chiplet |
| 360 | HBM, first chiplet |
| 372 | bottom layer, via capture layer |
| 374 | bottom layer backside contacts |
| 376 | bumps |
| 400 | large QCM interposer |
| 410.1-4 | chiplets, chip regions |
| 420.A1-4 | passive C2C connections |
| 420.B | diagonal bridge |
| 500 | chip |
| 550 | accelerator |
| 552 | bottom layer accelerator contacts |
| 555 | HBM IO |
| 560 | HBM |
| 562 | bottom layer HBM contacts |
| 565 | 3D IO to accelerator connector |
| 570 | SRAM |
| 572 | bottom layer SRAM contacts |
| 600 | manufacturing process for embodiment 1 |
| 605-645 | embodiment 1 manufacturing process operations |
| 700 | manufacturing process for embodiment 2 |
| 705-750 | embodiment 2 manufacturing process operations |

Recently, active interposers, waferscale processors, or packageless processors have been proposed. Active interposers enable additional functionality that may be used to design and package chips. Active interposers play the same role in packaging as a standard (or “passive”) interposer by providing interconnections between chiplets and connections to the substrate through TSVs—but they also include active circuitry built into the structure of the interposer. These active circuits may be built into silicon interposers, although other materials (e.g., glass) may be used as well.

Active circuits can be placed in both the chiplets and in the interposers, making use of active elements—these active elements may be any type of circuit. In some designs, circuits that process data or signals as part of in-package processing functions may be included directly on a chiplet, while system-level functions may be placed in the interposer.

Active components within an interposer can be of interest for I/O, power management, and many other reasons. However, producing large interposers with active components, especially across greater than one reticle field, can be prohibitively expensive. In addition, in many cases, active components may only be needed in certain regions.

Disclosed herein are alternate mechanisms for enabling active interposers or active interposer regions on larger-scale chips that include passive interposer regions. According to various embodiments disclosed, a structure and method for forming an active interposer in which active chips are inserted within trenches in a chip. This creates patches of active circuitry within a larger passive interposer structure. Various embodiments keep a top surface of the interposer substantially planar for subsequent chip joins. Backside processing of the interposer may entail forming contacts to both the passive as well as active portions of the interposer. This design may eliminate certain bumping issues with bridges and inserts patches of active interposers within a larger interposer structure. In general, the active portions of the interposer will have a different number of metal layers than the passive portions of the interposer. When multiple active interposers are embedded, they can be dissimilar to each other and can be in a different technology (e.g., 4 nm, 7 nm, etc.) than the chiplets that are attached to the top of the interposer.

### Embodiment 1

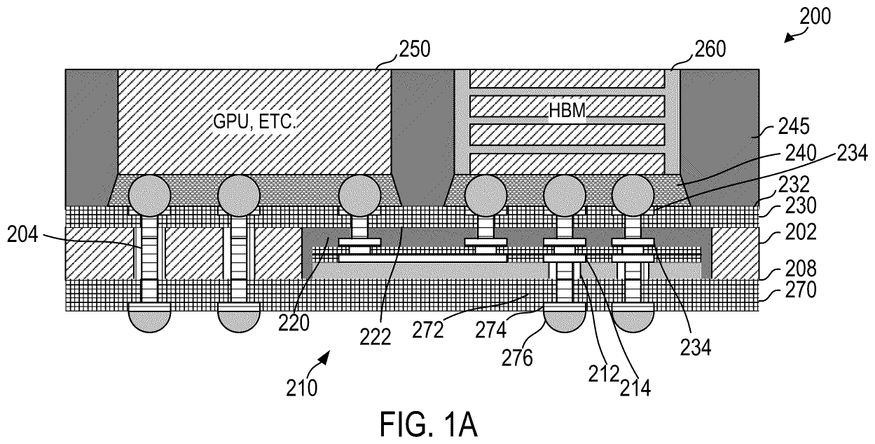

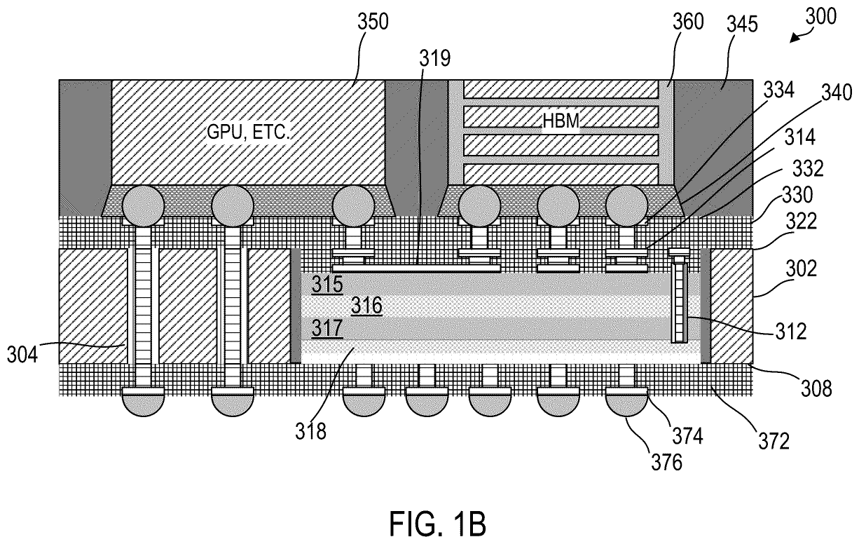

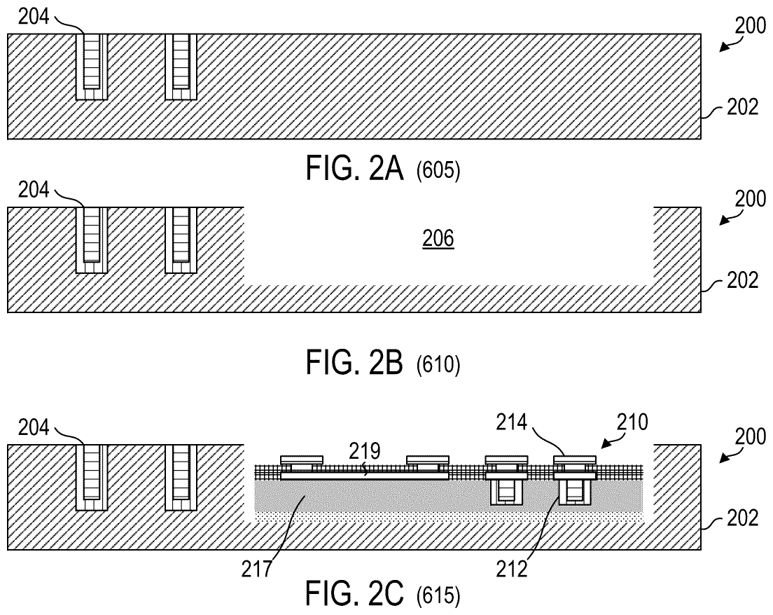

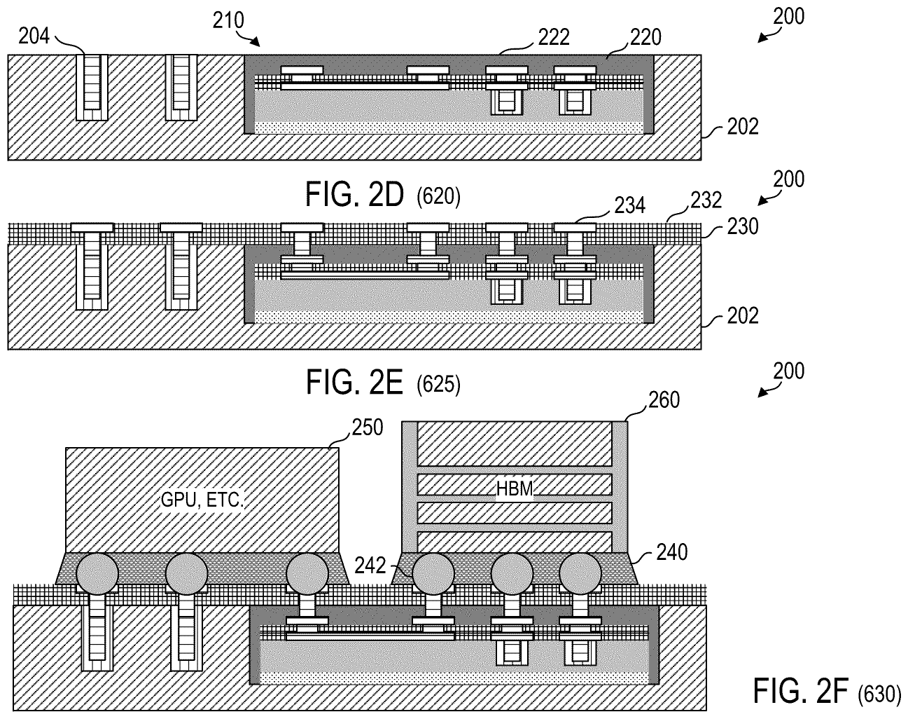

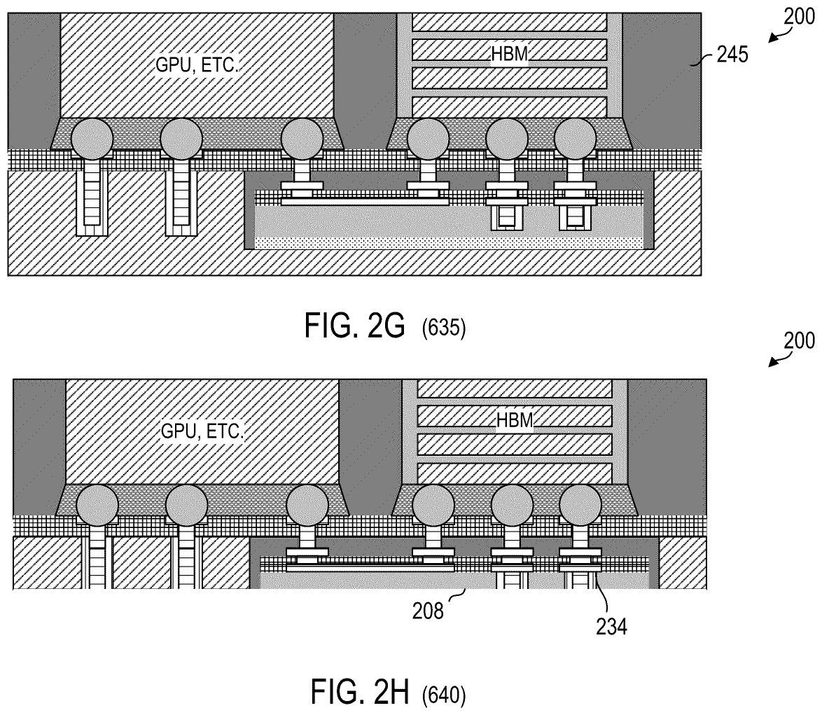

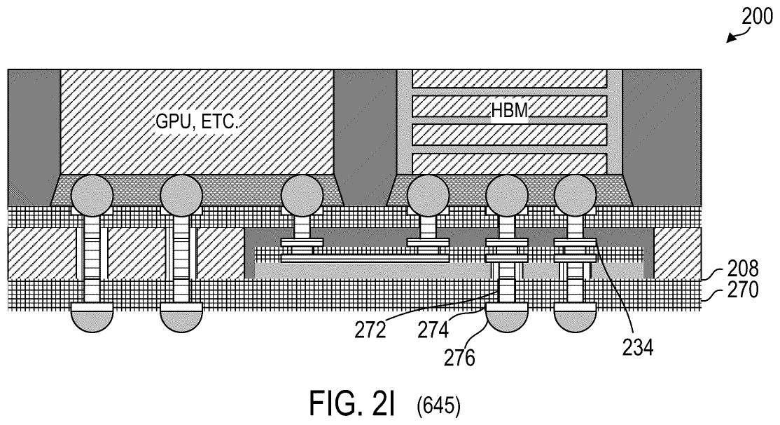

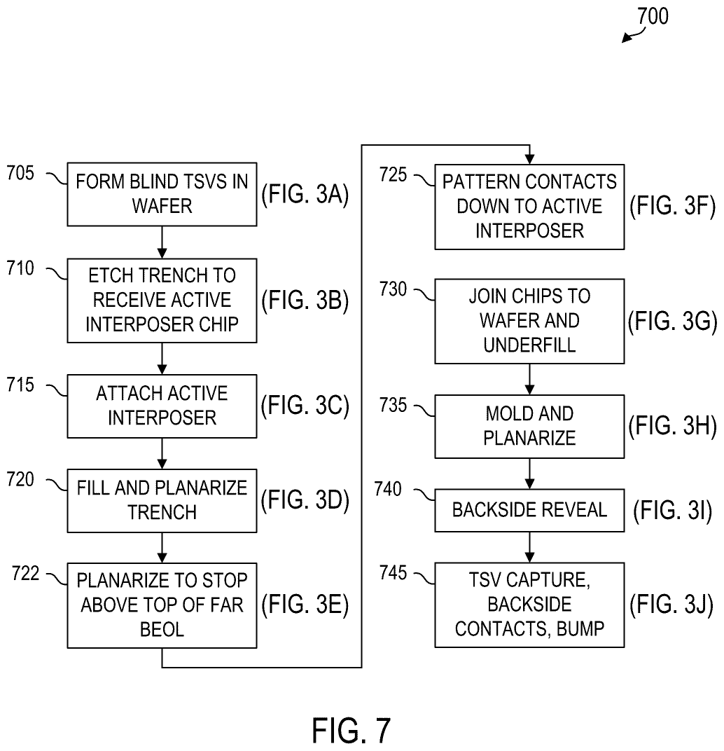

FIG. 1A is a cross-sectional side view of a semiconductor device 200 according to a first embodiment. The elements shown in FIG. 1A are described in more detail below in the context of a method of manufacturing. FIGS. 2A-2I are cross-sectional side views of the semiconductor device 200 according to the first embodiment after various operations of its manufacturing process 600 (FIG. 6). (FIG. 1B is a second embodiment described in more detail below.)

FIG. 2A is a cross-sectional side view of the semiconductor device 200 after operation 605 has been performed, which involves forming vias (also, blind through vias, such as blind through silicon vias (TSVs)) 204 in a chip 202. TSV is a packaging technology that replaces the conventional wires used to connect chips. In this packaging technology, chips are cut to a thickness of less than a sheet of paper and stacked. Then, each chip is punched with microscopic holes and connected by electrodes to the neighboring chips above and below. This permits chips to be stacked to achieve high capacity. It is characterized by substantial speed and power consumption improvements over conventional wire bonding methods used to connect chips.

FIG. 2B is a cross-sectional side view of the semiconductor device 200 after operation 610 has been performed, which involves etching an interposer trench 206 that may be used to receive an active interposer.

FIG. 2C is a cross-sectional side view of the semiconductor device 200 after operation 615 has been performed, which involves attaching the active interposer 210 (also “active interposer chip” herein), with interposer vias, or blind TSVs 212, having at least an active component layer 217) using, e.g., a die attach film (DAF) method. The DAF method may be used for stacked die applications or for thin die (<100 um) application to avoid broken wafer and die crack issues. A basic process flow for DAF assembly processing may involve die bonding followed by oven curing for, e.g., sixty minutes at 130° C. for strip-to-strip leadless package assembly. Active interposer contacts 214 are provided on a top surface of the active interposer 210. A (passive) interconnection 219 may be provided to connect various components together.

FIG. 2D is a cross-sectional side view of the semiconductor device 200 after operation 620 has been performed, which involves adding an interposer fill material 220 to fill the remaining portion of the interposer trench 206 and planarizing the top surface 222 of the fill material 220. The interposer fill material 220 in some embodiments may be an organic material, and in some other embodiments may be an inorganic material.

Organic options may include, for example, an epoxy resin having fillers, a molding compound (epoxy molding compound or other molding compound), a polymide, or any other suitable polymer. However, the interposer fill material 220 could be a hybrid material, whereby an organic polymer has inorganic fillers (which could even be conductors, or any other thermal conductive material). Purely inorganic fillers could be silicon oxide, silicon nitride, amorphous silicon, silicon germanium, or even metals. Any combination of the above may be suitable for the interposer fill material 220, and some embodiments may include combinations of inorganic and organic material sequentially.

Fill materials used in various embodiments may be provided to prevent the formation of voids or air pockets—these are to be avoided as they may impact device performance and reliability.

FIG. 2E is a cross-sectional side view of the semiconductor device 200 after operation 625 has been performed, which involves adding pattern contacts 234 down through the (interposer) pattern contacts layer 230 to contact the active interposer contacts 214 and any other necessary redistribution layer (RDL) contacts. These might include, e.g., the two contact to the left of the two rightmost contacts 232.

There can be other metal layers on the passive interposer region that need contacts through 230. The FIGS. show providing the pattern contacts layer 230 first before making contacts to the active interposer 210. However, it is also possible to first make a contact (via) to the active interposer 210 through the interposer fill material 220 and then deposit the pattern contacts layer 230 and continue building up the structure with further vias and lines as needed.

Also, although the FIGS. show only blind TSVs in the passive portions of the interposer before making the trench 206 for the active interposer 210, there could be metal lines/vias connected to the blind TSVs before making the trench. Therefore, the trench would pass through dielectric and silicon layers. The interposer layer 230 has a top surface 232 shown in FIG. 2E.

FIG. 2F is a cross-sectional side view of the semiconductor device 200 after operation 630 has been performed, which involves joining a GPU 250 and an HBM 260 to a top surface 232 of the interposer layer 230 (as shown in FIG. 2E) and, in some embodiments, providing an underfill 240. The joining of the GPU 250 and HBM 260 described herein are a specific embodiment of the more generic embodiment of joining a first chiplet 260 and a second chiplet 250. Use of the specific embodiment terms in the discussion below are for the sake of clarity and for illustrative purposes. However, these terms are used as proxies for the more generic chiplet terms. Therefore, any discussion below using the specific GPU and HBM examples should also be considered as disclosure for using the first and second chiplets.

The bonding of the chiplets 250, 260 shown in FIG. 2F illustrate micro controlled collapse chip connection (C4) chiplet bonding bumps 240. However, it is also possible to utilize hybrid bonding for this purpose as well. One example of this is copper-SiO2 hybrid bonding. Another option is the use of a copper-polymer hybrid bonding. If organic layers were removed from the chip (due, e.g., to temperature limitations), such hybrid bonding may be used to bond the chiplets to the interposer structure.

FIG. 2G is a cross-sectional side view of the semiconductor device 200 after operation 635 has been performed, which involves adding a mold fill layer 245 that surrounds at least a portion of the GPU 250 and HBM 260, and planarizing this layer.

FIG. 2H is a cross-sectional side view of the semiconductor device 200 after operation 640 has been performed, which involves planarizing the bottom of the chip 202 to produce a bottom surface 208 that reveals the blind TSVs 204, 212 and contacts 234.

FIG. 2I is a cross-sectional side view of the semiconductor device 200 after operation 645 has been performed, which involves a TSV capture by adding a bottom layer (also called a via capture layer) 270 at the bottom surface 208, and providing bottom layer backside contacts 274 that contact the contacts 234 and provide bumps 276 on the backside contacts 274 at bottom layer vias 272. These bumps 276 may be of a flip chip type, also referred to as a controlled collapse chip connection (C4) comprising solder bumps deposited on chip pads of the wafer.

### Embodiment 2

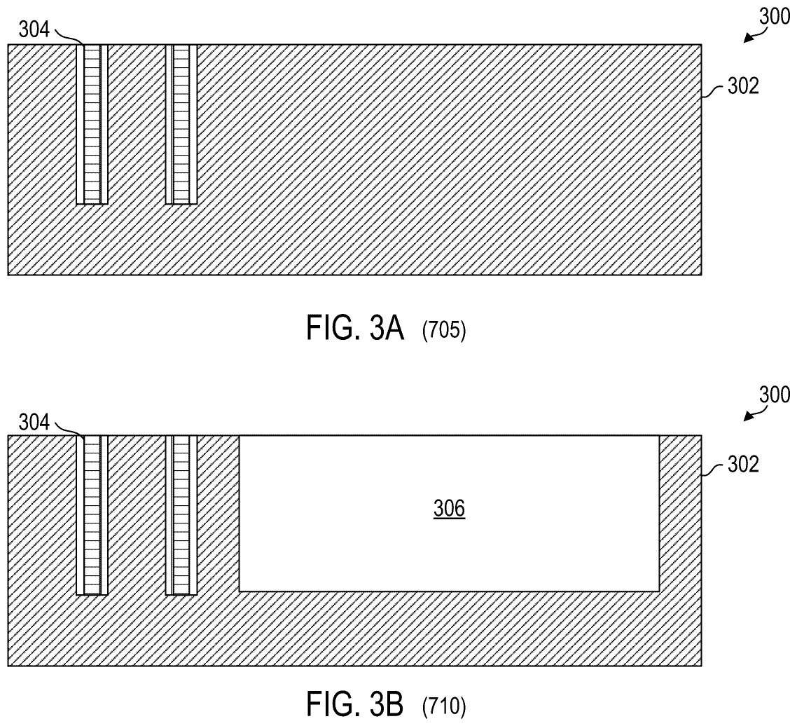

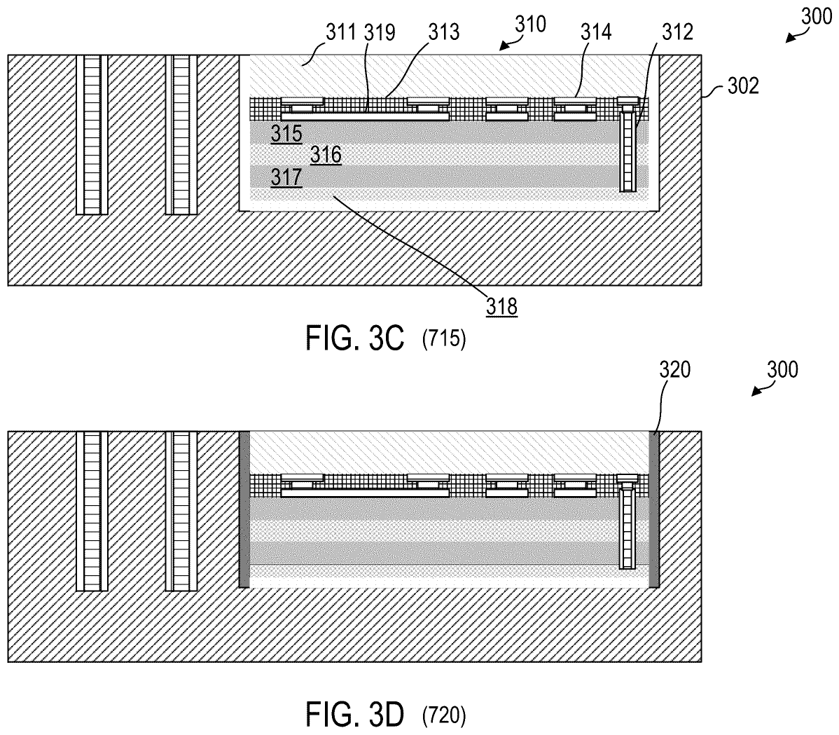

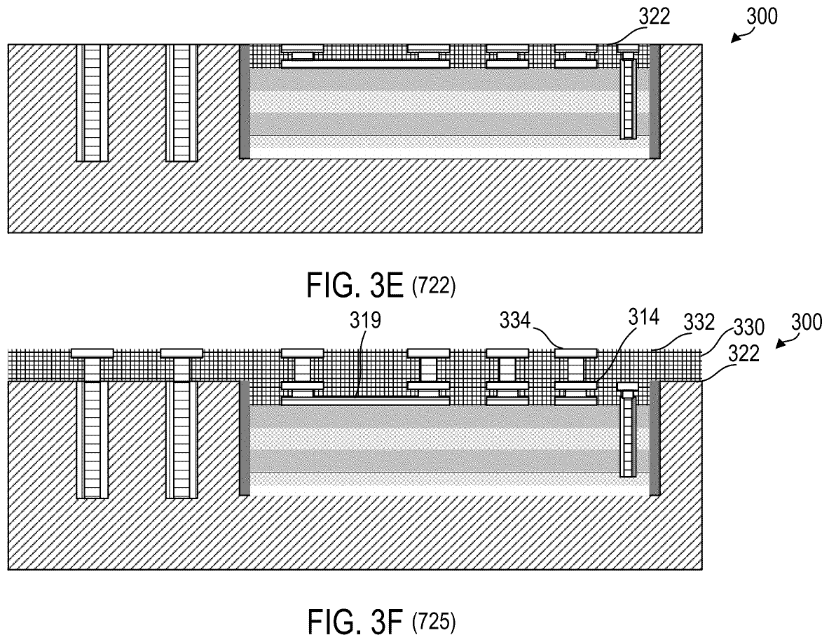

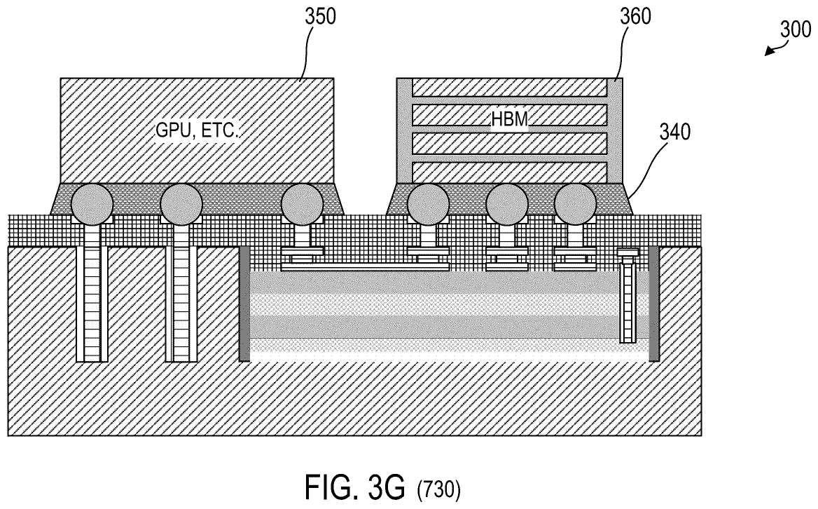

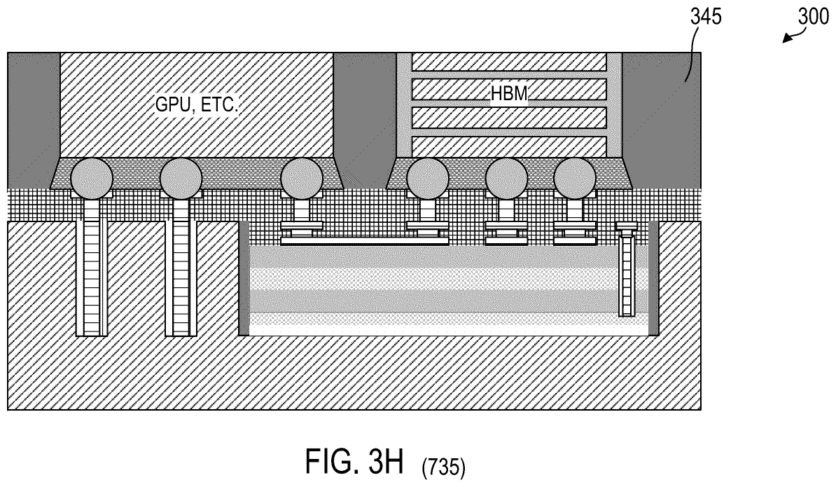

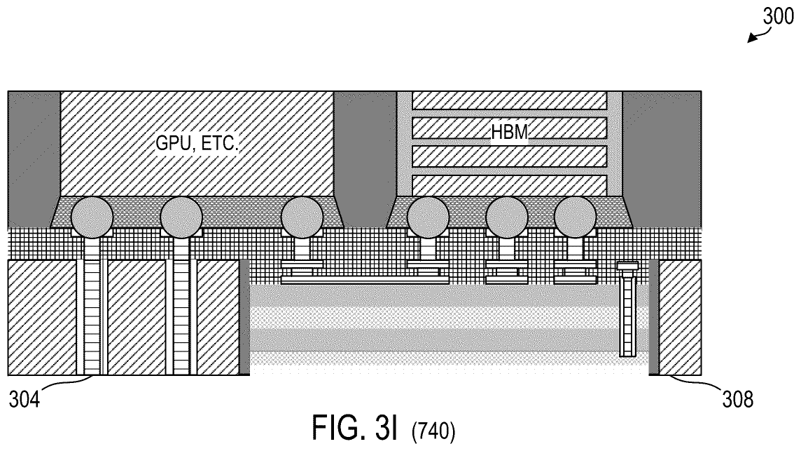

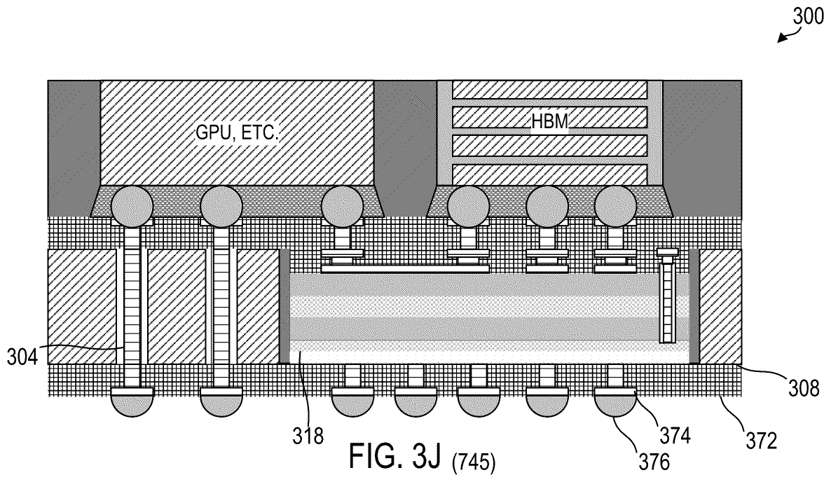

FIG. 1B is a cross-sectional side view a semiconductor device 300 according to a second embodiment. The elements shown in FIG. 1B are described in more detail below in the context of a method of manufacturing. FIGS. 3A-3J are cross-sectional side views of the semiconductor device 300 according to the first embodiment after various operations of its manufacturing process 700 (FIG. 7).

FIGS. 3A-3J are cross-sectional side views of a semiconductor device 300 according to a second embodiment throughout its manufacturing process 700 (FIG. 7).

FIG. 3A is a cross-sectional side view of the semiconductor device 300 after operation 705 has been performed, which involves forming blind through vias, such as blind through silicon vias (TSVs) 304 in a wafer, such as a silicon chip 302.

FIG. 3B is a cross-sectional side view of the semiconductor device 300 after operation 710 has been performed, which involves etching a trench 306 that may be used to receive an active interposer.

FIG. 3C is a cross-sectional side view of the semiconductor device 300 after operation 715 has been performed, which involves attaching the active interposer 310 (with blind TSVs 312) using a DAF method. Active interposer contacts 314 are provided on a top surface of the active interposer 310. The active interposer 310 used in this example comprises a carrier wafer portion 311 that covers over a top surface of the interposer contacts 314, including a far back-end-of-line (BEOL) layer 313. The active interposer 310 shown in this example comprises, in order below the far BEOL layer 313, a MIM capacitor, inductor layer 315, a lower BEOL layer 316, a switching devices layer 317, and a backside interconnection layer 318. The MIM capacitor could be above or below a layer with inductors. These layers/structures may be formed as part of a standard BEOL process. The inductors can be used as part of analog circuit or as part of a power regulator, etc. MIM capacitors or any other suitable capacitor may be part of a circuit or may be used for power integrity or even for ESD. A (passive) interconnection 319 may be provided to connect various components together.

FIG. 3D is a cross-sectional side view of the semiconductor device 300 after operation 720 has been performed, which involves adding a fill material 320 to fill the trench 306 and planarizing the top surface 322 (as shown in FIG. 3E) of the fill material 320.

FIG. 3E is a cross-sectional side view of the semiconductor device 300 after operation 722 has been performed, which involves planarizing the top surface 322 to a stop just above the top of the far BEOL layer 313.

FIG. 3F is a cross-sectional side view of the semiconductor device 300 after operation 725 has been performed, which involves adding pattern contacts 334 down through a pattern contacts layer 330 that is provided on the top surface 322 to contact the active interposer contacts 314 and any other necessary redistribution layer (RDL) contacts. The pattern contacts layer 330 has a top surface 332.

FIG. 3G is a cross-sectional side view of the semiconductor device 300 after operation 730 has been performed, which involves joining a GPU 350 (an example of a second chiplet) and an HBM 360 (an example of a first chiplet) to a top surface 332 (shown in FIG. 3F) of the interposer layer 330 and providing an underfill 340.

FIG. 3H is a cross-sectional side view of the semiconductor device 300 after operation 735 has been performed, which involves adding a mold fill layer 345 and planarizing this layer.

FIG. 3I is a cross-sectional side view of the semiconductor device 300 after operation 740 has been performed, which involves planarizing the bottom of the silicon chip 302 to produce a bottom surface 308 that reveals the blind TSVs 304.

FIG. 3J is a cross-sectional side view of the semiconductor device 300 after operation 745 has been performed, which involves a TSV capture by adding a bottom layer 372 (also called a via capture layer) at the bottom surface 308, and providing bottom layer backside contacts 374 that connect to contacts in the blind TSVs 304 or backside contacts 374 that go through the bottom layer 372 and contact the backside interconnects on the backside interconnection layer 318. Operation 750 may also provide bumps 376 on the backside contacts 374.

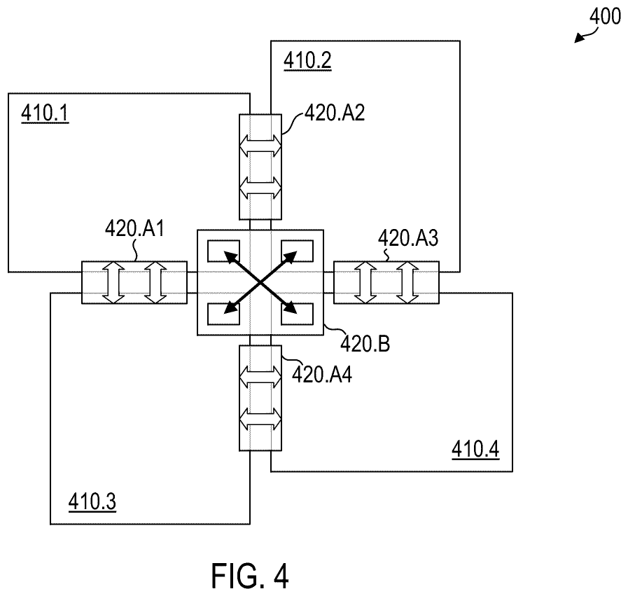

FIG. 4 is a block diagram (top view, not to scale) of an example use case of the technology described above. It shows a large QCM interposer 400 having a small active region. FIG. 4 shows four chiplets 410.1, 410.2, 410.3, 410.4 that may have very large substrates, e.g., on the order of 400-500 mm². For chip-to-chip (C2C) data and coherence, it may be necessary to provide, e.g., 2000 inputs and outputs which require Si-like BEOL ground rules. Here the diagonal may be ˜1.4 times longer than an adjacent C2C and may need an active bridge for C2C coherence.

One possible solution for such constraints is to use five bridges (four passive and one active). However, this possible solution may be complicated to assemble and test. Another possible solution might be the use of integrated thin-film high-density organic package (i-THOP®) techniques. This technique would also make use of an active bridge. However, this possible solution requires two complicated and costly packaging techniques. Furthermore, the iTHOP design rules may not be sufficient to achieve the design objectives.

One effective solution using the techniques described above use an Si interposer with an embedded active chip. This solution provides a single component to provide a maximum bandwidth for passive and active interconnect regions. Here, the four chiplets 410 (or chip regions 410) may be connected by high bandwidth adjacent C2C connections (passive) 420.A1, 420.A2, 420.A3, 420.A4 and a diagonal bridge (active) 420.B. The diagonal bridge 420.B can have more metal layers for cris-crossing, and it may have more active components for longer distance communications. This example shows an extremely large interposer, at least 1.5×1 reticle field, up to 2×2, but the active region has a 2× wiring layer count that is less than 50 mm² (7×7 mm). To generalize, passive interposers can be very large, whereby multiple reticle fields are stitched together to pattern a region that is larger than a single reticle field. However, it is desirable to keep the active region as small as possible to maintain high yield and low cost. This supports the notion that one can insert a small embedded active interposer region that only occupies a small area, and this region may have more metal layers than the passive interposer region.

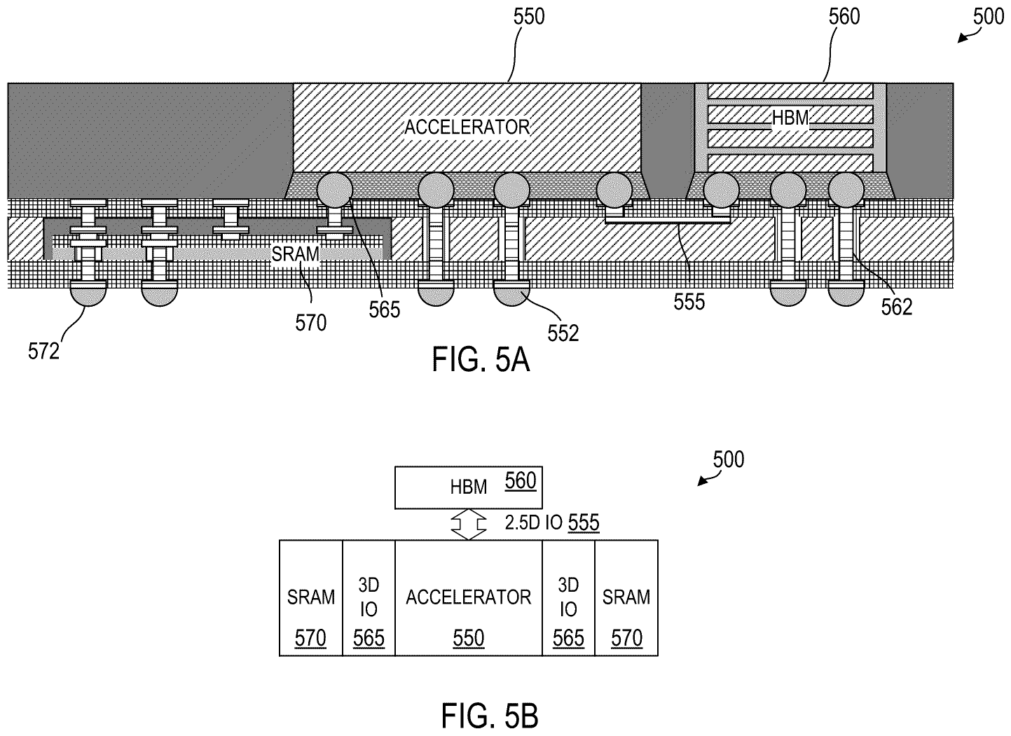

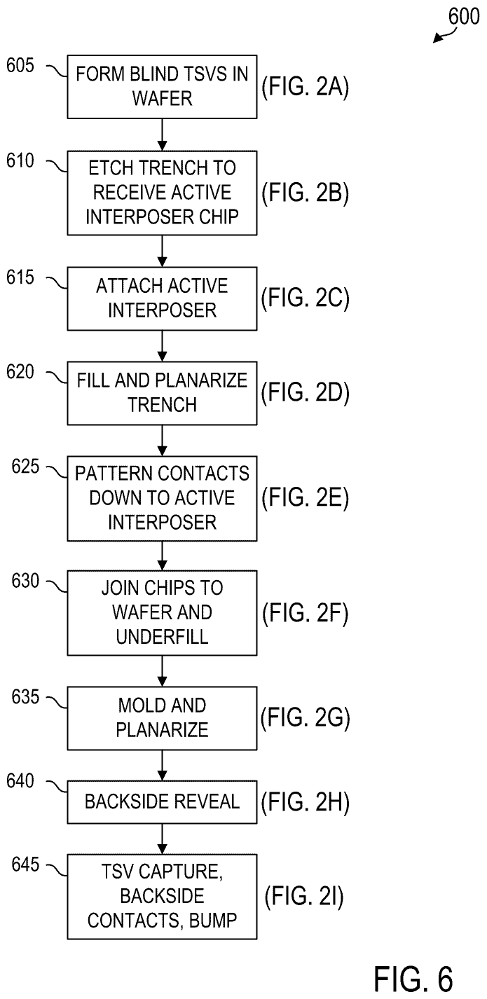

FIG. 5A is a cross-sectional side view of a chip 500 illustrating a decoupling of the accelerator power distribution and scratchpad design (i.e., a memory that provides temporary storage of data, such as a cache). The chip 500 comprises an accelerator 550, an HBM 560, and static RAM (SRAM) 570. The HBM 560 may be provided standard HBM power through bottom layer HBM contacts 562 and connect to the accelerator 550 through 2.5D HBM IO 555. The SRAM 570 may be provided SRAM power through bottom layer SRAM contacts 572, and be connected to the accelerator 550 through a 3D IO to accelerator connector 565. Power to the accelerator 550 may be provided via bottom layer accelerator contacts 552—the power to the accelerator 550 is not blocked by the SRAM 570, and thus, there is no thermal impact.

FIG. 5A illustrates the active portion comprising an SRAM 570, this may constitute any form of active circuitry and is not limited to the example of SRAM shown in the drawings. Furthermore, although FIG. 5A illustrates two chiplets (accelerator 550 and HBM 560), the inventive concepts to not require both for implementation.

FIG. 5B is a top view of the chip described in FIG. 5A, and the component descriptions are the same. Note that the HBM 560 may join directly to an SRAM 570 chip or the accelerator 550, depending on the architecture.

In some embodiments, the active components may first be embedded into the wafer, and then the TSVs are drilled after the embedding. In some embodiments, the TSVs can be drilled from the backside of the interposers after grinding down and revealing the active chip. In some embodiments, a similar structure may be implemented using a glass wafer or panel. Also, a non-CoWoS interposer process flow can be followed in which the interposer (with embedded chips) is first completed before the chip join. Other elements, such as a silicon lid structure (to limit molding compound use), can be incorporated into the process.

FIG. 6 is a flowchart illustrating an example of an embodiment of a method for manufacturing the chip according to the first embodiment, whose operations have been described above.

FIG. 7 is a flowchart illustrating an example of an embodiment of a method for manufacturing the chip according to the second embodiment, whose operations have been described above.

### Examples

Various examples provided below illustrate various embodiments of the invention.

Example 1 is a semiconductor device comprising a wafer with an active interposer comprising one or more active components in an active component layer. The semiconductor device comprises a first chiplet that is mounted on the wafer and above the active interposer, a second chiplet that is mounted on the wafer and above the active interposer, and an interconnect layer having an interconnection that bridges between the first chiplet and the second chiplet. The interconnect layer is configured to transfer at least one of power and a signal from a bottom-side bump on a bottom side of the wafer to at least one of the first chiplet and the second chiplet, directly or indirectly, through a TSV of the active interposer.

This Example creates active portions of an interposer and maintains a top surface of the interposer substantially planar for all subsequent chip joins. Backside contacts are provided to enable contacting the active portions.

Example 2 is a semiconductor device of Example 1 in which the wafer comprises an interposer trench within which the active interposer is positioned. The semiconductor device further comprising an interposer fill material that fills a remaining portion of the interposer trench that is not filled by the active interposer. Advantageously, this provides a basis for keeping a top surface of the interposer planar for subsequent chip joins.

Example 3 is a semiconductor device of Examples 1 and 2, where the interposer fill material is an organic material. Use of an organic material may provide good insulation and have low dielectric constant properties.

Example 4 is a semiconductor device of Examples 1-3, where the active interposer further comprises a far BEOL layer, at least one layer comprising MIM capacitors and inductors, a lower BEOL layer, and a backside interconnection layer. An active component layer comprises switching devices, and the backside contacts are connected through the backside interconnection layer to the via of the active interposer. This design may maximize the flexibility in locating the active regions of the interposer and the connections to these active regions.

Example 5 is a semiconductor device of Examples 1-4, where the active interposer comprises silicon. The use of silicon takes advantage of established device manufacturing techniques.

Example 6 is a semiconductor device of Examples 1-5, where the active interposer comprises passive regions without active components, the passive regions comprising backside contacts. This configuration is advantageous in that it provides the ability to provide interconnections to both active and passive regions of the device.

Example 7 is a semiconductor device of Examples 1-6, where the first chiplet is a high bandwidth memory. The design of this semiconductor device advantageously allows for very high communication rates due to the nature of the interconnects of the device.

Example 8 is a semiconductor device of Examples 1-7, where the second chiplet is a graphics processing unit. The design of this semiconductor device advantageously allows for very high communication rates due to the nature of the interconnects of the device.

Example 9 is a method for manufacturing a semiconductor device. The method comprises forming vias in a wafer, forming an interposer trench in the wafer, and attaching an active interposer comprising one or more active components and interposer vias to the wafer and within the interposer trench. The method further comprises filling, with an interposer fill material, and planarizing the interposer trench. The method further comprises adding pattern contacts layer with pattern contacts on top of the active interposer and that contact the interposer vias. The method further comprises joining a first chiplet and a second chiplet to the semiconductor device above the active interposer that contact the pattern contacts. The method further comprises providing a mold fill layer that surrounds at least a portion of the first chiplet and the second chiplet and is above the pattern contacts layer and planarizing the mold fill layer, revealing a backside on a bottom surface of the active interposer, and providing a bottom layer below the bottom surface comprising backside contacts and bumps.

This Example creates a semiconductor device having active portions of an interposer and maintains a top surface of the interposer substantially planar for all subsequent chip joins. Backside contacts are provided to enable contacting the active portions.

Example 10 is a method of Example 9, where at least one of the vias is a blind through silicon via. This manufacturing technique allows an accurate placement of circuitry and enhances signal routing.

Example 11 is a method of Examples 9 and 10, further comprising planarizing the bottom layer to reveal the blind through silicon via. This allows the attachment of contacts that are used to interface the semiconductor device with other components.

Example 12 is a semiconductor device comprising a chip, an active interposer region of an active interposer comprising one or more active components in an active component layer, a passive interposer region that contains no active components, and an interconnect layer that is configured to transfer at least one of power and a signal from a bottom-side bump on a bottom side of the chip to a device located above the active interposer region, directly or indirectly, through a via of the active interposer. This design allows access to a bottom portion of the chip by the active interposer region and any device(s) that are connected above the active interposer on the chip.

Example 13 is a semiconductor device of Example 12, where the active interposer region comprises a different number of layers than the active interposer region. The use of additional layers may support the active components that are present in the active interposer region.

Example 14 is a semiconductor device of Examples 12 or 13, where the active interposer is embedded within a trench formed in the chip. The location of the active interposer within a trench lends itself to planarizing a top layer of the chip upon which chiplets may be mounted.

Example 15 is a semiconductor device of Examples 12-14 where: a) contact vias to the active interposer are formed in a planarizing layer located only in a region above the embedded active interposer, or b) another layer is formed across the active interposer region and the passive interposer region into which contact vias are formed. The user of these structures can simplify the addition of chiplets and their interconnections on the chip as a whole.

Example 16 is a semiconductor device of Examples 12-15, further comprising a first chiplet that is mounted on the chip and above the active interposer and is connected to the active interposer through a via. Incorporating a chiplet onto the semiconductor device allows the structure of a potentially fully-functioning chip.

Example 17 is a semiconductor device of Example 16, where the first chiplet partially overlaps the active interposer region. This design advantageously allows the appropriate vias to be formed through which contacts may be run allowing power and communications between the active interposer and the chiplet.

Example 18 is a semiconductor device of Example 16, wherein the first chiplet fully overlaps the active interposer region. This provides the advantages discussed with respect to Example 17, but further addresses the compactness of the chip design.

Example 19 is a semiconductor device of Example 16, further comprising a second chiplet that is mounted on the chip and above the active interposer, and an interconnection that bridges between the first chiplet and the second chiplet. The inclusion of additional chiplets and the intercommunications capability allows the functionality of the overall chip design to expand.

Example 20 is a semiconductor device of Example 19, where the first chiplet and the second chiplet are both connected to bumps on the bottom of the chip through vias. This configuration provides maximum flexibility in terms of mounting and configuring the overall chip design.

What is claimed is:

1. A semiconductor device comprising:
a chip;
an active interposer comprising one or more active components in an active component layer;
a first chiplet that is mounted on the chip and above the active interposer;
a second chiplet that is mounted on the chip and above the active interposer; and
an interconnect layer having an interconnection that bridges between the first chiplet and the second chiplet and is configured to transfer at least one of power and a signal from a bottom-side bump on a bottom side of the chip to at least one of the first chiplet and the second chiplet, directly or indirectly, through a TSV of the active interposer.

2. The semiconductor device of claim 1:
wherein the chip comprises an interposer trench within which the active interposer is positioned; and
the semiconductor device further comprising an interposer fill material that fills a remaining portion of the interposer trench that is not filled by the active interposer.

3. The semiconductor device of claim 2, wherein the interposer fill material is selected from the group consisting of an organic material, an inorganic material, a hybrid material, and a combination of organic and inorganic material sequentially.

4. The semiconductor device of claim 1, wherein:
the active interposer further comprises a far BEOL layer, a lower BEOL layer, and a backside interconnection layer;
the active component layer comprises switching devices; and
the backside contacts are connected through the backside interconnection layer to the via of the active interposer.

5. The semiconductor device of claim 1, wherein the active interposer comprises silicon.

6. The semiconductor device of claim 1, wherein the active interposer comprises passive regions without active components, the passive regions comprising backside contacts.

7. The semiconductor device of claim 1, wherein the first chiplet is a high bandwidth memory.

8. The semiconductor device of claim 1, wherein the second chiplet is a graphics processing unit.

9. A method for manufacturing a semiconductor device, comprising:
forming vias in a chip;
forming an interposer trench in the chip;
attaching an active interposer comprising one or more active components and interposer vias to the chip and within the interposer trench;
filling, with an interposer fill material, and planarizing the interposer trench;
adding pattern contacts layer with pattern contacts on top of the active interposer and that contact the interposer vias;
joining a first chiplet and a second chiplet to the semiconductor device above the active interposer that contact the pattern contacts;
providing a mold fill layer that surrounds at least a portion of the first chiplet and the second chiplet and is above the pattern contacts layer and planarizing the mold fill layer;
revealing a backside on a bottom surface of the active interposer; and
providing a bottom layer below the bottom surface comprising backside contacts and bumps.

10. The method of claim 9, wherein at least one of the vias is a blind through silicon via.

11. The method of claim 10, further comprising planarizing the bottom layer to reveal the blind through silicon via.

12. A semiconductor device comprising:
a chip;
an active interposer region of an active interposer comprising one or more active components in an active component layer;
a passive interposer region that contains no active components; and
an interconnect layer that is configured to transfer at least one of power and a signal from a bottom-side bump on a bottom side of the chip to a device located above the active interposer region, directly or indirectly, through a via of the active interposer.

13. The semiconductor device of claim 12, wherein the active interposer region comprises a different number of layers than the active interposer region.

14. The semiconductor device of claim 12, wherein the active interposer is embedded within a trench formed in the chip.

15. The semiconductor device of claim 14 wherein:
a) contact vias to the active interposer are formed in a pattern contacts layer located only in a region above the embedded active interposer; or
b) another layer is formed across the active interposer region and the passive interposer region into which contact vias are formed.

16. The semiconductor device of claim 12, further comprising a first chiplet that is mounted on the chip and above the active interposer and is connected to the active interposer through a via.

17. The semiconductor device of claim 16, wherein the first chiplet partially overlaps the active interposer region.

18. The semiconductor device of claim 16, wherein the first chiplet fully overlaps the active interposer region.

19. The semiconductor device of claim 16, further comprising:
a second chiplet that is mounted on the chip and above the active interposer; and
an interconnection that bridges between the first chiplet and the second chiplet.

20. The semiconductor device of claim 19, wherein the first chiplet and the second chiplet are both connected to bumps on the bottom of the chip through vias.
